(19) United States
(12) Patent Application Publication
(10) Pub. No.: US 2019/0304813 A1
(43) Pub. Date: Oct. 3, 2019

(54) COMPONENT FOR SEMICONDUCTOR PRODUCTION DEVICE

(71) Applicant: NGK SPARK PLUG CO., LTD., Nagoya-shi, Aichi (JP)

(72) Inventors: Kohei MITSUYA, Inuyama-shi (JP); Hideo TANGE, Ichinomiya-shi (JP); Motoki HOTTA, Kasugai-shi (JP); Takamichi OGAWA, Nagoya-shi (JP)

(21) Appl. No.: 16/316,367

(22) PCT Filed: Jul. 13, 2017
(86) PCT No.: PCT/JP2017/025609

§ 371 Date: Jan. 9, 2019

(30) Foreign Application Priority Data
Jul. 20, 2016 (JP) 2016-142494

(51) Int. Cl. H01L 21/67; H05B 3/14; H01L 21/687

(52) U.S. Cl. CPC H01L 21/67103; H01L 2021/6015; H01L 21/68757; H05B 3/143

(57) ABSTRACT

The scattering of a rare earth hydroxide is suppressed, and the loss of bond strength between a first ceramic member and a second ceramic member is reduced.

A semiconductor production device component includes a first ceramic member including an AlN-based material, a second ceramic member including an AlN-based material, and a joint layer disposed between the first ceramic member and the second ceramic member so as to join the first ceramic member and the second ceramic member to each other, wherein the joint layer includes a perovskite oxide represented by ABO₃ (wherein A is a rare earth element, and B is Al) and includes no rare earth single oxide containing exclusively a rare earth element and oxygen.

### TECHNICAL FIELD

The technique disclosed in the present specification relates to components for semiconductor production devices.

### BACKGROUND ART

Susceptors (heating devices) are used as components in semiconductor production devices. For example, a susceptor includes a plate-shaped ceramic holding member having a built-in heater, a cylindrical ceramic supporting member disposed on one side of the holding member, and a joint layer disposed between the holding member and the supporting member so as to join the opposed surfaces of the holding member and supporting member to each other. The opposite surface of the holding member is a holding surface on which a wafer will be mounted. The susceptor heats a wafer mounted on the holding surface by means of heat generated by the application of a voltage to the heater. Some known susceptors of this class have a holding member and a supporting member which are each made of materials based on AlN (aluminum nitride) having relatively high thermal conductivity, and a joint layer which is made of materials including a rare earth single oxide that contains exclusively a rare earth element and oxygen (see, for example, Patent Literature 1).

### CITATION LIST

### Patent Literature

PTL 1: Japanese Unexamined Patent Application Publication No. 10-242252

### SUMMARY OF INVENTION

### Technical Problem

A rare earth single oxide reacts with water to form a rare earth hydroxide. This rare earth hydroxide occurs more easily as the temperature increases. A susceptor is often washed with chemicals, water and the like, for example, before use and is dried at a high temperature. If the joint layer in the susceptor includes a rare earth single oxide, the rare earth single oxide contained in the joint layer is reacted with water to form a rare earth hydroxide. When dried, this rare earth hydroxide is scattered as powder and often contaminates a wafer. Further, the scattering of the rare earth hydroxide leaves hollows in the joint layer, possibly causing a decrease in the bond strength between the holding member and the supporting member.

The above problem is encountered not only in the joining of a holding member and a supporting member into a susceptor, but also in the joining of ceramic members for constituting a holding device such as, for example, an electrostatic chuck. Further, the above problem exists not only in holding devices, but also in the joining of ceramic members for constituting semiconductor production device components such as, for example, shower heads.

The present specification discloses a technique capable of solving the problem discussed above.

### Solution to Problem

The technique disclosed in the present specification may be realized, for example, in the forms described below.

(1) A semiconductor production device component disclosed in the present specification includes a first ceramic member including an AlN-based material, a second ceramic member including an AlN-based material, and a joint layer disposed between the first ceramic member and the second ceramic member so as to join the first ceramic member and the second ceramic member to each other, wherein the joint layer includes a perovskite oxide represented by ABO₃ (wherein A is a rare earth element, and B is Al) and includes no rare earth single oxide containing exclusively a rare earth element and oxygen. In the semiconductor production device component, the joint layer includes a perovskite oxide represented by ABO₃ (wherein A is a rare earth element, and B is Al (aluminum)) and includes no rare earth single oxide containing exclusively a rare earth element and oxygen. This perovskite oxide is a stable substance that is much less reactive with water than rare earth single oxides. Thus, it is possible to prevent the scattering of a rare earth hydroxide and to reduce the loss of bond strength between the first ceramic member and the second ceramic member.

(2) A semiconductor production device component disclosed in the present specification includes a first ceramic member including an AlN-based material, a second ceramic member including an AlN-based material, and a plurality of joint sections disposed between the first ceramic member and the second ceramic member so as to join the first ceramic member and the second ceramic member to each other, wherein the joint sections include a perovskite oxide represented by ABO₃ (wherein A is a rare earth element, and B is Al) and include no rare earth single oxide containing exclusively a rare earth element and oxygen. In the semiconductor production device component, the joint sections include a perovskite oxide represented by ABO₃ (wherein A is a rare earth element, and B is Al (aluminum)) and include no rare earth single oxide containing exclusively a rare earth element and oxygen. This perovskite oxide is a stable substance that is much less reactive with water than rare earth single oxides. Thus, it is possible to prevent the scattering of a rare earth hydroxide and to reduce the loss of bond strength between the first ceramic member and the second ceramic member.

(3) In the above semiconductor production device components, the rare earth element in the perovskite oxide may include at least one of Gd, Nd, Tb, Eu and Y. The semiconductor production device component with this configuration can benefit from suppressed scattering of a rare earth hydroxide and reduced loss of bond strength between the first ceramic member and the second ceramic member, by virtue of the joint layer or joint sections including a perovskite oxide having at least one of Gd, Nd, Tb, Eu and Y.

The technique disclosed in the present specification may be implemented in various forms and may be embodied in the forms of semiconductor production device components, for example, holding devices such as electrostatic chucks and vacuum chucks, heating devices such as susceptors, and shower heads.

### BRIEF DESCRIPTION OF DRAWINGS

FIG. 1 is a perspective view schematically illustrating an appearance configuration of a susceptor 100 according to an embodiment.

FIG. 2 is a view schematically illustrating an XZ sectional configuration of a susceptor 100 according to an embodiment.

FIG. 3 is a diagram illustrating the results of XRD measurement of a susceptor 100 according to an embodiment.

FIG. 4 is a diagram illustrating the results of XRD measurement of a susceptor of COMPARATIVE EXAMPLE.

### DESCRIPTION OF EMBODIMENTS

### A. Embodiment

### A-1. Configuration of Susceptor 100

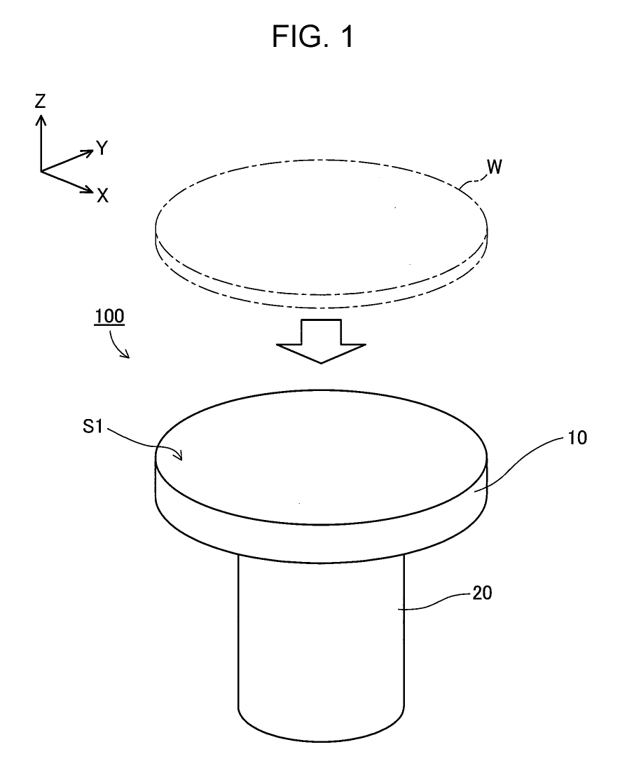

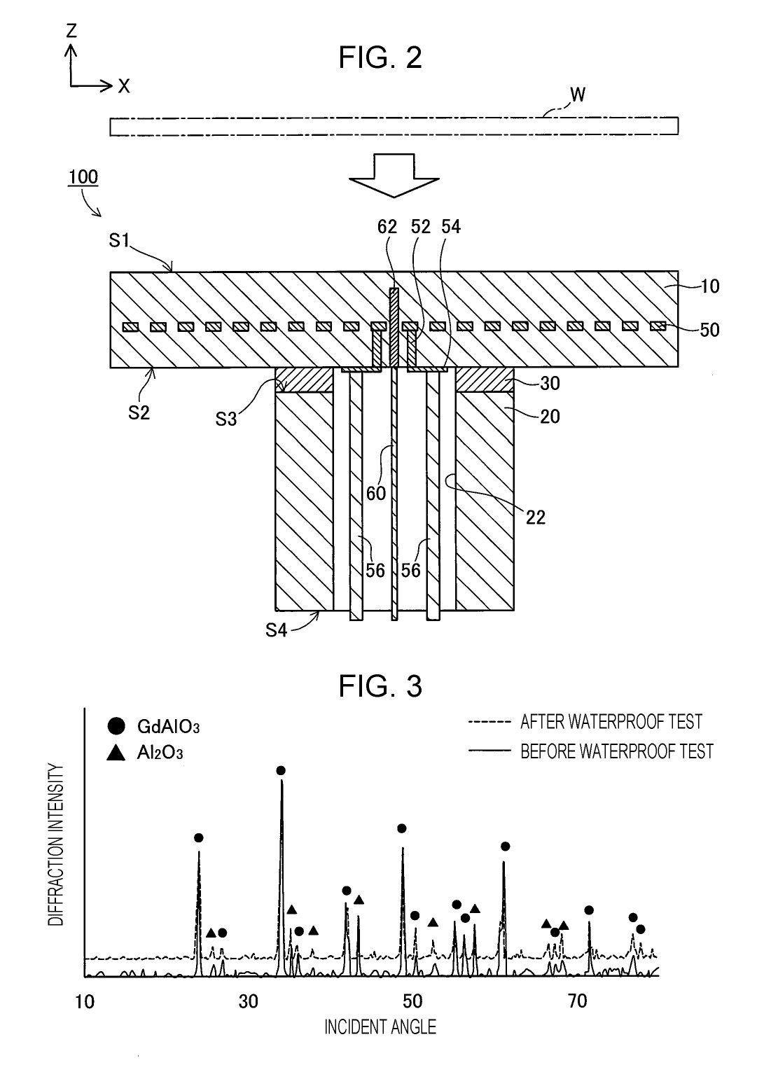

FIG. 1 is a perspective view schematically illustrating an appearance configuration of a susceptor 100 according to the present embodiment. FIG. 2 is a view schematically illustrating an XZ sectional configuration of the susceptor 100 according to the present embodiment. In these figures, X, Y and Z axes perpendicular to one another are shown to indicate directions. In the present specification, for the sake of convenience, the positive direction on the Z axis is defined as the upward direction, and the negative direction on the Z axis as the downward direction. However, the susceptor 100 may be actually arranged in a direction which does not conform to such definitions. The susceptor 100 corresponds to the semiconductor production device component in the claims.

The susceptor 100 is a device which holds a workpiece (for example, a wafer W) and heats the workpiece to a predetermined processing temperature, and is installed in, for example, a thin-film forming device (for example, a CVD device or a sputtering device) or an etching device (for example, a plasma etching device) used in the manufacturing of semiconductor devices. The susceptor 100 includes a holding member 10 and a supporting member 20 which are arranged adjacent to each other in a predetermined arrangement direction (in the present embodiment, in the vertical (Z axis) direction). The holding member 10 and the supporting member 20 are arranged so that the lower surface of the holding member 10 (hereinafter, written as the “holder-side joint surface S2”) and the upper surface of the supporting member 20 (hereinafter, written as the “support-side joint surface S3”) are opposed to each other in the arrangement direction. The susceptor 100 further includes a joint layer 30 disposed between the holder-side joint surface S2 of the holding member 10 and the support-side joint surface S3 of the supporting member 20. The holding member 10 corresponds to the first ceramic member in the claims, and the supporting member 20 to the second ceramic member in the claims.

### (Holding Member 10)

For example, the holding member 10 is a plate-shaped member having a flat circular surface, and is made of a ceramic based on AlN (aluminum nitride). Here, the term “based” means that the component has the largest proportion (weight proportion). For example, the diameter of the holding member 10 is about 100 mm to 500 mm. For example, the thickness of the holding member 10 is about 3 mm to 15 mm.

Within the holding member 10, a heater 50 is disposed which is composed of a linear resistive heating element formed of a conductive material (such as, for example, tungsten or molybdenum). A pair of ends of the heater 50 is arranged near the central portion of the holding member 10. Further, a pair of vias 52 is disposed within the holding member 10. Each via 52 is a linear conductor extending in the vertical direction. The upper ends of the vias 52 are connected to the respective ends of the heater 50, and the lower ends of the vias 52 are disposed on the holder-side joint surface S2 of the holding member 10. Further, a pair of receiving electrodes 54 is disposed near the central portion of the holder-side joint surface S2 of the holding member 10. The receiving electrodes 54 are connected to the respective lower ends of the vias 52 so as to establish an electrical connection between the heater 50 and the receiving electrodes 54.

### (Supporting Member 20)

For example, the supporting member 20 is a cylindrical member extending in the vertical direction, and has a through hole 22 extending in the vertical direction from the support-side joint surface S3 (the upper surface) to the lower surface S4. Similarly to the holding member 10, the supporting member 20 is made of a ceramic based on AlN. The supporting member 20 has an outer diameter of, for example, about 30 mm to 90 mm, an inner diameter of, for example, about 10 mm to 60 mm, and a vertical length of, for example, about 100 mm to 300 mm. The through hole 22 of the supporting member 20 accommodates a pair of electrode terminals 56. Each electrode terminal 56 is a rod-shaped conductor extending in the vertical direction. The upper ends of the electrode terminals 56 are brazed to the respective receiving electrodes 54. When a voltage is applied from a power source (not shown) to the pair of electrode terminals 56, the heater 50 is caused to generate heat, which heats the holding member 10 and then heats the wafer W held on the upper surface (hereinafter, written as the “holding surface S1”) of the holding member 10. For example, the heater 50 is arranged substantially concentrically as viewed in the Z direction so as to be capable of heating the holding surface S1 of the holding member 10 as uniformly as possible. Further, the through hole 22 of the supporting member 20 accommodates two metal wires 60 as a thermocouple (only one metal wire is illustrated in FIG. 2). Each metal wire 60 extends in the vertical direction, and an upper end portion 62 of each metal wire 60 is buried in the central portion of the holding member 10. This structure allows the temperature inside the holding member 10 to be measured, and the temperature of the wafer W to be controlled based on the measurement result.

### (Joint Layer 30)

The joint layer 30 is a sheet layer shaped like a circular ring, and joins together the holder-side joint surface S2 of the holding member 10 and the support-side joint surface S3 of the supporting member 20. The joint layer 30 is formed of materials which include GdAlO₃, Al₂O₃ (alumina) and no rare earth single oxides containing exclusively a rare earth element and oxygen. The joint layer 30 has an outer diameter of, for example, about 30 mm to 90 mm, an inner diameter of, for example, about 10 mm to 60 mm, and a thickness of, for example, about 50 μm to 70 μm. The phrase “no rare earth single oxide(s)” means that the content of a rare earth single oxide(s) in the joint layer 30 is less than 2 wt %.

### A-2. Method for Producing Susceptor 100

Next, a method for producing a susceptor 100 of the present embodiment will be described. First, a holding member 10 and a supporting member 20 are provided. As mentioned earlier, the holding member 10 and the supporting member 20 are both made of a ceramic based on AlN. The holding member 10 and the supporting member 20 are producible by known methods, and thus the description of the methods for their production will be omitted.

Next, the holder-side joint surface S2 of the holding member 10 and the support-side joint surface S3 of the supporting member 20 are lapped so that the joint surfaces S2 and S3 have a surface roughness of not more than 1 μm and a flatness of not more than 10 μm. Next, a joint agent is applied to at least one of the holder-side joint surface S2 of the holding member 10 and the support-side joint surface S3 of the supporting member 20. Specifically, GdAlO₃ powder and Al₂O₃ powder are mixed together in a predetermined ratio and are further mixed with an acrylic binder and butylcarbitol to give a paste-like joint agent. The composition ratio of the materials forming the paste-like joint agent is preferably, for example, 48 mol % GdAlO₃ and 52 mol % Al₂O₃. Next, the paste-like joint agent is printed, through a mask, onto at least one of the holder-side joint surface S2 of the holding member 10 and the support-side joint surface S3 of the supporting member 20. Thereafter, the support-side joint surface S3 of the supporting member 20 and the holder-side joint surface S2 of the holding member 10 are superimposed one on top of the other via the paste-like joint agent, thereby forming a stack of the holding member 10 and the supporting member 20.

Next, the stack of the holding member 10 and the supporting member 20 is placed into a hot press furnace, and is heated while being pressed in nitrogen. Consequently, the paste-like joint agent is melted to form a joint layer 30, and the holding member 10 and the supporting member 20 are joined together by the joint layer 30. The pressure during this thermal pressure bonding is preferably set in the range of not less than 0.1 MPa and not more than 15 MPa. Controlling the pressure during the thermal pressure bonding at 0.1 MPa or above ensures that the members will be joined together without gaps therebetween even in the presence of irregularities such as waves on the surface of the members that are to be joined (the holding member 10 and the supporting member 20), thus making it possible to prevent an early decrease in the bond strength between the holding member 10 and the supporting member 20 (the bond strength of the joint layer 30). By controlling the pressure during the thermal pressure bonding at 15 MPa or below, the holding member 10 can be prevented from cracking and the supporting member 20 from being deformed. Incidentally, the joint surfaces S2 and S3 are subjected to a pressure of 0.2 kgf/cm² to 3 kgf/cm².

During the thermal pressure bonding, the temperature is preferably raised to 1750° C. When the temperature is raised to 1750° C. during the thermal pressure bonding, the temperature is kept at 1750° C. for about 10 minutes and thereafter the temperature inside the hot press furnace is lowered to room temperature. After the thermal pressure bonding, post treatments (such as polishing of the circumferences and the upper and lower surfaces, and the formation of terminals) are performed as required. A susceptor 100 having the aforementioned configuration is produced by the production method described above.

### A-3. Performance Evaluation

Susceptor 100 of EXAMPLE and susceptor of COMPARATIVE EXAMPLE were tested as described below to evaluate their performance.

### A-3-1. Example and Comparative Example

The susceptor 100 of EXAMPLE is one produced by the production method described hereinabove. The susceptor of COMPARATIVE EXAMPLE includes a holding member, a supporting member and a joint layer. The susceptor 100 of EXAMPLE and the susceptor of COMPARATIVE EXAMPLE are common in the following.

(Configuration of holding member)
Material: AlN-based ceramic
Diameter: 100 mm to 500 mm
Thickness: 3 mm to 15 mm

### (Configuration of Supporting Member)

Material: AlN-based ceramic
Outer diameter: 30 mm to 90 mm
Inner diameter: 10 mm to 60 mm
Vertical length: 100 mm to 300 mm

### (Profile of Joint Layer)

Outer diameter: 30 mm to 90 mm
Inner diameter: 10 mm to 60 mm
Thickness: 50 μm to 70 μm

The susceptor 100 of EXAMPLE and the susceptor of COMPARATIVE EXAMPLE differ in the following.

### (Materials of Joint Layer)

The materials of the joint layer 30 in the susceptor 100 of EXAMPLE included GdAlO₃ and Al₂O₃, and included no rare earth single oxides containing exclusively a rare earth element and oxygen.

The materials of the joint layer in the susceptor of COMPARATIVE EXAMPLE included rare earth single oxide Gd₂O₃.

The susceptor of COMPARATIVE EXAMPLE was produced basically in the same manner as the susceptor 100 of EXAMPLE produced by the aforementioned method, except that Gd₂O₃ powder, instead of the GdAlO₃ powder and the Al₂O₃ powder, was mixed with an acrylic binder and butylcarbitol to give a paste-like joint agent.

### A-3-2. Evaluation Procedures

### (Evaluation of Bond Strength of Joint Layer)

To evaluate the bond strength of the joint layer, the susceptor 100 of EXAMPLE and the susceptor of COMPARATIVE EXAMPLE were subjected to He (helium) leak test. In the He leak test, a He leak detector (not shown) is connected to, for example, the lower open end of the supporting member 20 of the susceptor 100 of EXAMPLE, and He gas is blown to the outer periphery of the joint layer 30. The presence or absence of He leakage through the joint layer 30 was checked based on the detection results from the He leak detector. He leakage being detected means that hollows are present in the joint layer 30 and the bond strength is low. In the present embodiment, the susceptor 100 of EXAMPLE was tested for He leakage for the first time immediately after production. Next, the susceptor 100 of EXAMPLE was ultrasonically washed in a solvent and was subsequently ultrasonically washed in pure water. After the washing, the susceptor 100 of EXAMPLE was placed into a dryer and was dried at 120° C. for 4 hours. The dried susceptor 100 of EXAMPLE was tested for He leakage for the second time.

### (Evaluation of Suppression of Hydroxide Formation in Joint Layer)

To evaluate the suppression of hydroxide formation in the joint layer, the susceptor 100 of EXAMPLE and the susceptor of COMPARATIVE EXAMPLE were subjected to appearance inspection, SEM (scanning electron microscope) inspection, EDS (energy dispersive X-ray spectrometry) and XRD (X-ray diffraction) measurement before and after waterproof testing. In the waterproof test, for example, the susceptor 100 of EXAMPLE was arranged in an autoclave and was allowed to stand at a high temperature and a high pressure (123° C., 0.22 MPa) for 12 hours using saturated vapor. (The amount of saturated vapor was 1.2 kg/m³.) In the appearance inspection, the joint layer 30 of the susceptor 100 of EXAMPLE was cut and the cross section was visually examined. In the SEM inspection, a cross section of the joint layer 30 of the susceptor 100 of EXAMPLE was observed by SEM. In the EDS and XRD measurement, a cross section of the joint layer 30 of the susceptor 100 of EXAMPLE was analyzed by EDS for elemental analysis, and by XRD measurement to identify the configuration of the joint layer 30.

### A-3-3. Evaluation Results:

### (Evaluation of Bond Strength of Joint Layer)

The susceptor 100 of EXAMPLE was found to be free of He leakage in the first and second He leak tests. Although the susceptor of COMPARATIVE EXAMPLE was free of He leakage in the first He leak test, He leakage was detected in the second He leak test.

### (Evaluation of Suppression of Hydroxide Scattering in Joint Layer)

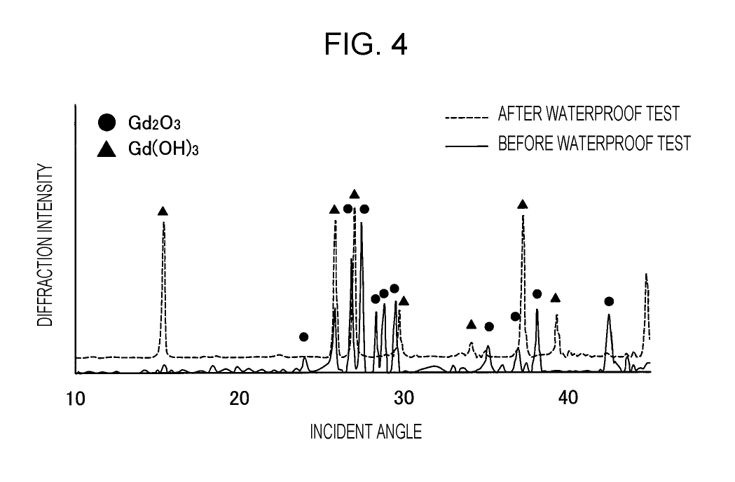

FIG. 3 is a diagram illustrating the results of XRD measurement of the susceptor 100 of EXAMPLE, and FIG. 4 is a diagram illustrating the results of XRD measurement of the susceptor of COMPARATIVE EXAMPLE. In the susceptor 100 of EXAMPLE, the appearance inspection and the SEM inspection did not show any differences in cross sections of the joint layer 30 before and after the waterproof test. In the EDS and the XRD measurement, as illustrated in FIG. 3, the joint layer 30 was shown to include GdAlO₃, Al₂O₃ and no rare earth single oxide both before and after the waterproof test, and the configuration (such as the composition ratio) of the joint layer 30 remained the same before and after the waterproof test.

In the susceptor of COMPARATIVE EXAMPLE, the appearance inspection and the SEM inspection did not show any abnormalities before the waterproof test, but the cross section of the joint layer 30 after the waterproof test was found to contain particles attached to portions thereof or to have been partly collapsed. According to the EDS and the XRD measurement, as illustrated in FIG. 4, the joint layer included Gd₂O₃ alone before the waterproof test, but the joint layer after the waterproof test exclusively contained Gd(OH)₃. In other words, in the susceptor of COMPARATIVE EXAMPLE, the material forming the joint layer changed from Gd₂O₃ to Gd(OH)₃ during the waterproof test.

### A-4. Effects of Present Embodiment

The joint layer of the susceptor of COMPARATIVE EXAMPLE included rare earth single oxide Gd₂O₃. When washed, Gd₂O₃ reacted with water to form the rare earth hydroxide Gd(OH)₃. When the joint layer was thereafter dried at a high temperature, this Gd(OH)₃ was scattered as powder, and the scattering of Gd(OH)₃ left hollows in the joint layer, thus causing a decrease in the bond strength of the joint layer. Probably because of these, the susceptor after the waterproof test was found to leak He in the He leak test, to have abnormalities such as powder attached to a cross section of the joint layer 30 in the appearance inspection and the SEM inspection, and to contain Gd(OH)₃ as the joint layer-forming material in the EDS and the XRD measurement.

In the susceptor 100 of EXAMPLE, the joint layer 30 included GdAlO₃, Al₂O₃ and no rare earth single oxide. The GdAlO₃ is a perovskite oxide. Since the perovskite oxides are stable substances that are much less reactive with water than rare earth single oxides, the joint layer 30 of the susceptor 100 of EXAMPLE can benefit from suppressed scattering of a rare earth hydroxide and reduced loss of bond strength of the joint layer.

### B. Modified Examples

The technique disclosed in the present specification is not limited to the embodiment illustrated above, and various modifications are possible without departing from the spirit thereof. For example, the following modifications are possible.

In the embodiment described above, the holding member 10 and the supporting member 20 may be joined together via a plurality of joint sections instead of the joint layer 30. Specifically, a plurality of joint sections may be dispersed on a single virtual plane perpendicular to the direction in which the holding member 10 and the supporting member 20 are opposed to each other, and the holding member 10 and the supporting member 20, with the joint sections disposed between the holding member 10 and the supporting member 20, may be partly connected to each other via AlN particles which are the material forming the holding member 10 and the supporting member 20.

In the embodiment and the modified example described above, for example, a second joint layer (second joint sections) having a different composition from the joint layer 30 (the joint sections) may be arranged together with the joint layer 30 (the joint sections) between the holding member 10 and the supporting member 20. That is, the holding member 10 and the supporting member 20 may be joined together via a plurality of joint layers or a plurality of types of joint sections having different compositions.

The ceramics forming the holding member 10 and the supporting member 20 in the embodiment and the modified examples described above are based on AlN (aluminum nitride) and may contain other elements.

In the embodiment and the modified examples described above, the materials forming the joint layer 30 (the joint sections) may include a perovskite oxide other than GdAlO₃ (the perovskite oxide being represented by ABO₃ (wherein A is a rare earth element, and B is Al)). The rare earth element preferably includes at least one of Gd, Nd, Tb, Eu and Y. As described in the embodiment above, the occurrence of rare earth hydroxide can be suppressed by mixing a perovskite oxide with alumina and sintering the mixture.

The method for producing the susceptor 100 described in the aforementioned embodiment is only illustrative, and various modifications are possible.

The present invention is applicable not only to the susceptors 100, but also to other semiconductor production device components, for example, other types of heating devices such as polyimide heaters, holding devices (for example, electrostatic chucks and vacuum chucks) which have a ceramic plate and a base plate and are configured to hold a workpiece on the surface of the ceramic plate, and shower heads.

### REFERENCE SIGNS LIST

10: HOLDING MEMBER 20: SUPPORTING MEMBER 22: THROUGH HOLE 30: JOINT LAYER 50: HEATER 52: VIA 54: RECEIVING ELECTRODE 56: ELECTRODE TERMINAL 60: METAL WIRE 62: UPPER END PORTION 100: SUSCEPTOR S1: HOLDING SURFACE S2: HOLDER-SIDE JOINT SURFACE S3: SUPPORT-SIDE JOINT SURFACE S4: LOWER SURFACE W: WAFER

What is claimed is:

1. A semiconductor production device component comprising:
a first ceramic member including an AlN-based material,
a second ceramic member including an AlN-based material, and
a joint layer disposed between the first ceramic member and the second ceramic member so as to join the first ceramic member and the second ceramic member to each other, wherein
the joint layer comprises a perovskite oxide represented by ABO₃ (wherein A is a rare earth element, and B is Al) and comprises no rare earth single oxide containing exclusively a rare earth element and oxygen.

2. A semiconductor production device component comprising:
a first ceramic member including an AlN-based material,
a second ceramic member including an AlN-based material, and
a plurality of joint sections disposed between the first ceramic member and the second ceramic member so as to join the first ceramic member and the second ceramic member to each other, wherein
the joint sections comprise a perovskite oxide represented by ABO₃ (wherein A is a rare earth element, and B is Al) and comprise no rare earth single oxide containing exclusively a rare earth element and oxygen.

3. The semiconductor production device component according to claim 1, wherein the rare earth element in the perovskite oxide includes at least one of Gd, Nd, Tb, Eu and Y.

4. The semiconductor production device component according to claim 2, wherein the rare earth element in the perovskite oxide includes at least one of Gd, Nd, Tb, Eu and Y.
